(19) United States
(12) Patent Application Publication
(10) Pub. No.: US 2025/0311302 A1
(43) Pub. Date: Oct. 2, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Meng-Huan JAO, Taichung (TW); Yi Hsing YU, Hsinchu (TW); Sheng-Tsung WANG, Hsinchu (TW); Huan-Chieh SU, Changhua (TW); Chih-Hao WANG, Hsinchu (TW)

(21) Appl. No.: 18/792,620

(22) Filed: Aug. 2, 2024

Related U.S. Application Data
(60) Provisional application No. 63/570,289, filed on Mar. 27, 2024.

(51) Int. Cl. H01L 29/423; H01L 21/768; H01L 21/8234; H01L 23/528; H01L 27/088; H01L 29/06; H01L 29/08; H01L 29/66; H01L 29/775; H01L 29/786

(52) U.S. Cl. CPC H10D 30/6735; H01L 21/7684; H01L 23/5283; H10D 30/014; H10D 30/43; H10D 30/6757; H10D 62/121; H10D 62/151; H10D 64/017; H10D 84/013; H10D 84/038; H10D 84/83

(57) ABSTRACT

Embodiments of the present disclosure provide a semiconductor device structure and methods of forming the same. The structure includes a gate electrode layer disposed over a substrate, a first source/drain region disposed over the substrate, a conductive contact disposed over the first source/drain region, a first dielectric layer disposed over the gate electrode layer and the conductive contact, a first conductive feature disposed in the first dielectric layer, a second conductive feature disposed in the first dielectric layer, and a second dielectric layer disposed on the first dielectric layer. The second dielectric layer is in contact with a portion of a side surface of the second conductive feature.

### CROSS-REFERENCE TO RELATED APPLICATIONS

This application claims priority to U.S. Provisional Application Ser. No. 63/570,289 filed Mar. 27, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure, in accordance with some embodiments.

FIGS. 7A-12A are cross-sectional side views of various stages of manufacturing the semiconductor device structure taken along line A-A of FIG. 6, in accordance with some embodiments.

FIGS. 7B-12B are cross-sectional side views of various stages of manufacturing the semiconductor device structure taken along line B-B of FIG. 6, in accordance with some embodiments.

FIGS. 7C-12C are cross-sectional side views of various stages of manufacturing the semiconductor device structure taken along line C-C of FIG. 6, in accordance with some embodiments.

FIGS. 13A-13I are cross-sectional side views of various stages of manufacturing the semiconductor device structure taken along line A-A of FIG. 6, in accordance with some embodiments.

FIGS. 14A-14B are cross-sectional side views of various stages of manufacturing the semiconductor device structure taken along line A-A of FIG. 6, in accordance with alternative embodiments.

FIGS. 15A-15G are cross-sectional side views of various stages of manufacturing the semiconductor device structure taken along line A-A of FIG. 6, in accordance with alternative embodiments.

FIGS. 16A-16B are cross-sectional side views of various stages of manufacturing the semiconductor device structure taken along line A-A of FIG. 6, in accordance with alternative embodiments.

FIGS. 17A-17E are cross-sectional side views of various stages of manufacturing the semiconductor device structure taken along line A-A of FIG. 6, in accordance with alternative embodiments.

FIG. 18 is a cross-sectional side view of one of various stages of manufacturing the semiconductor device structure taken along line A-A of FIG. 6, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

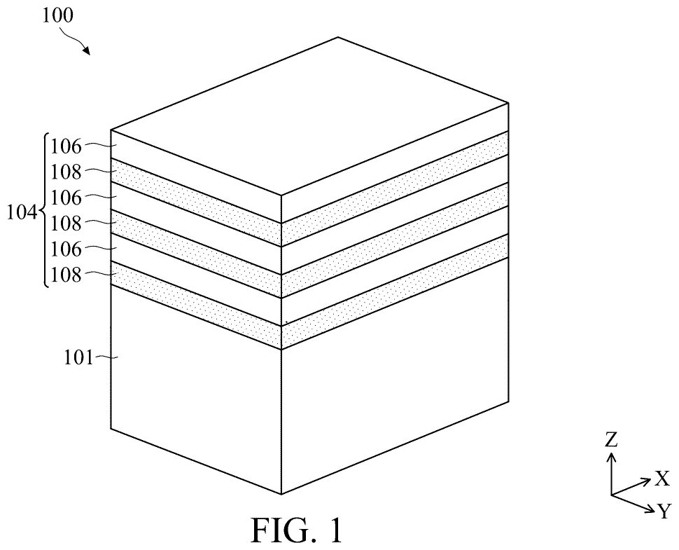

FIGS. 1-13I show exemplary processes for manufacturing a semiconductor device structure 100 according to embodiments of the present disclosure. It is understood that additional operations can be provided before, during, and after processes shown by FIGS. 1-13I, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

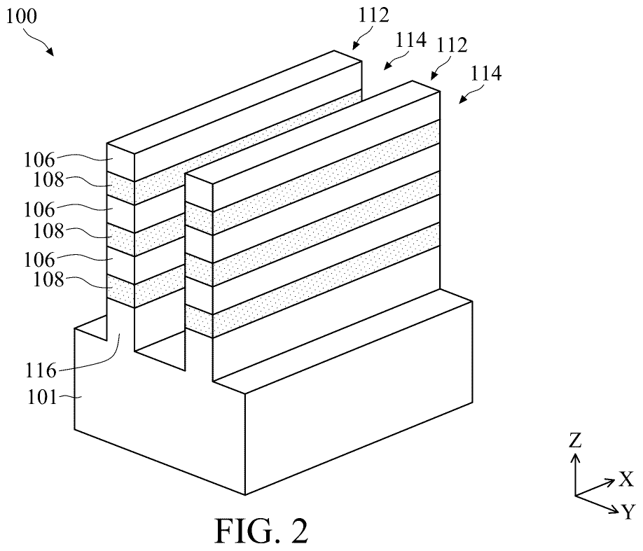

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking clement including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

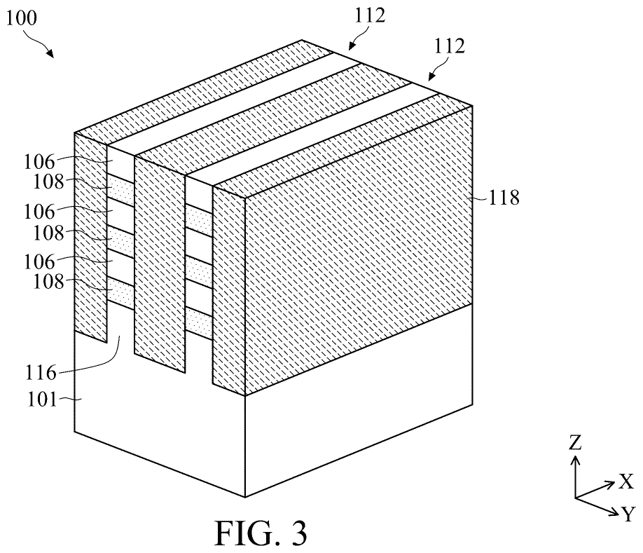

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

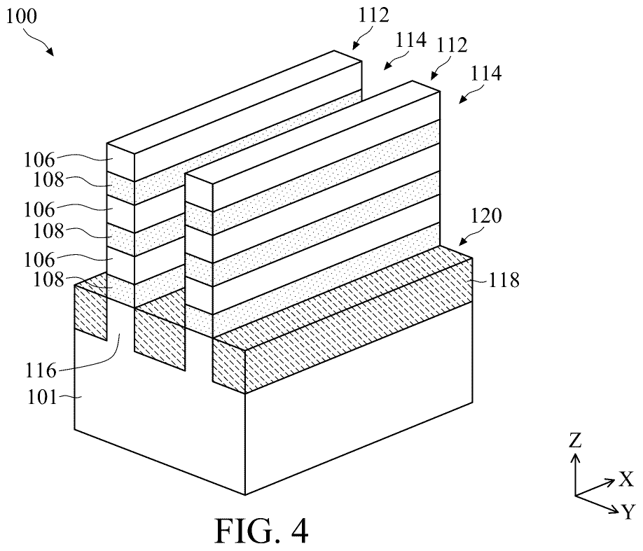

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101.

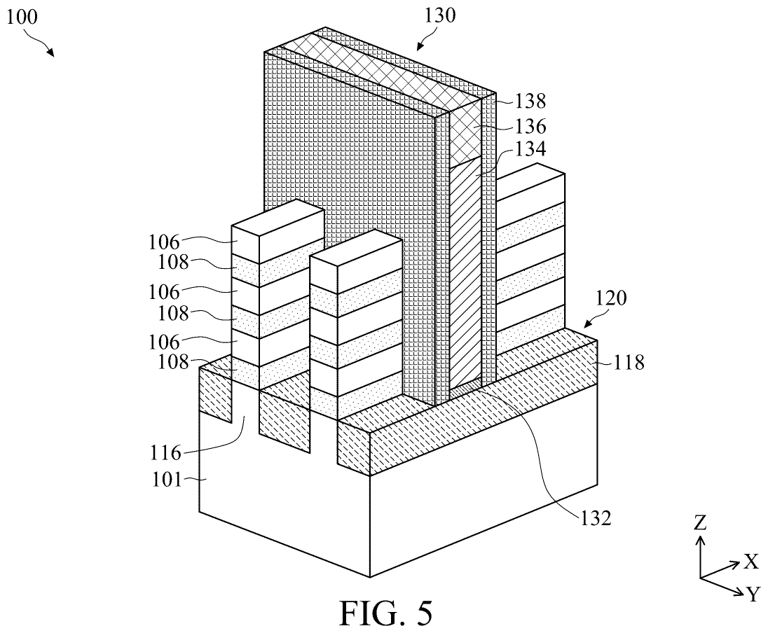

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Spacers 138 are then formed on sidewalls of the sacrificial gate structures 130. The spacers 138 may be formed by conformally depositing one or more layers for the spacers 138 and anisotropically etching the one or more layers, for example. In some embodiments, the spacers 138 are also formed on sidewalls of the exposed portions of the fin structures 112. While one sacrificial gate structure 130 is shown, two or more sacrificial gate structures 130 may be arranged along the X direction in some embodiments. In some embodiments, a contact poly pitch (CPP), which is a minimum center-to-center distance between adjacent sacrificial gate electrode layers 134, ranges from about 35 nm to about 100 nm.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100.

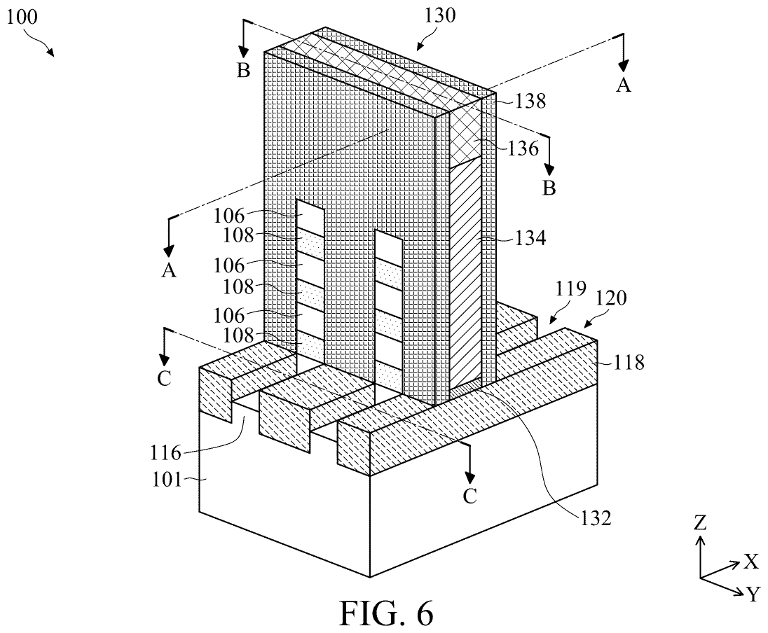

In FIG. 6, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant.

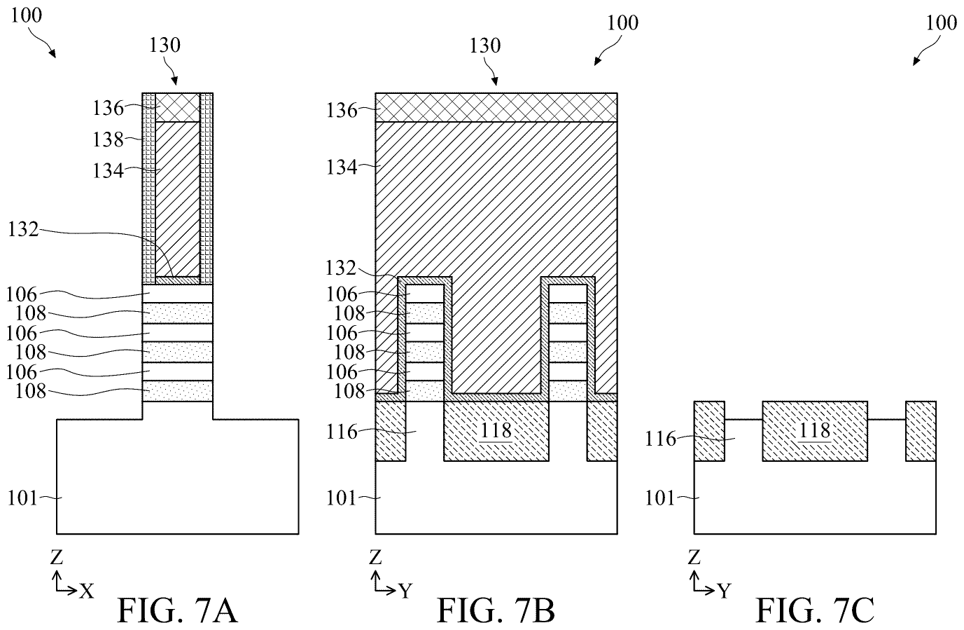

FIGS. 7A, 7B, and 7C are cross-sectional side views of the semiconductor device structure 100 taken along line A-A, line B-B, and line C-C of FIG. 6, respectively.

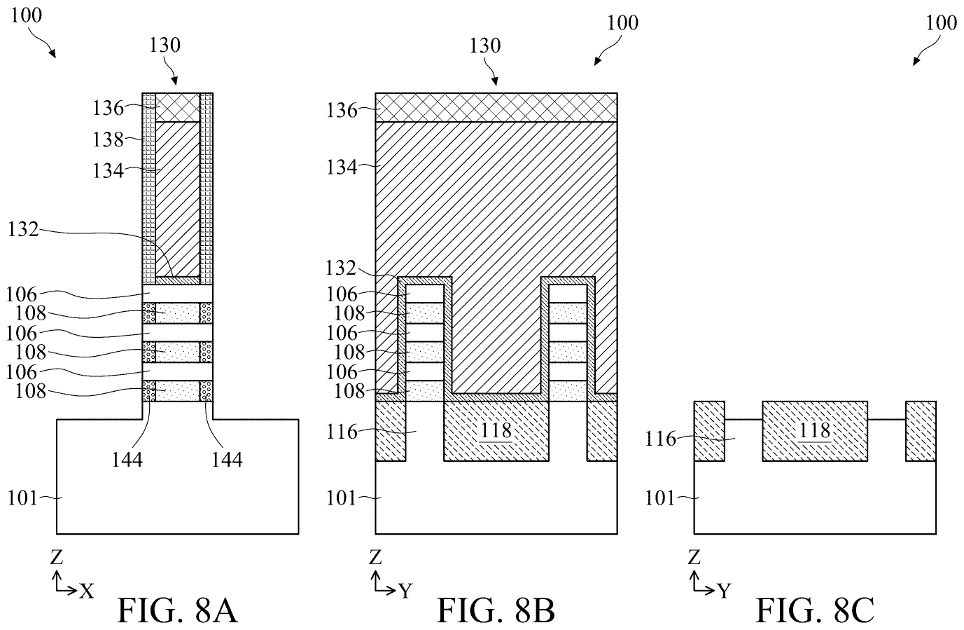

FIGS. 8A, 8B, and 8C are cross-sectional side views of one of various stages of manufacturing the semiconductor device structure 100 taken along line A-A, line B-B, and line C-C of FIG. 6, respectively, in accordance with some embodiments. As shown in FIG. 8A, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SIN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

FIGS. 9A, 9B, and 9C are cross-sectional side views of one of various stages of manufacturing the semiconductor device structure 100 taken along line A-A, line B-B, and line C-C of FIG. 6, respectively, in accordance with some embodiments. As shown in FIGS. 9A and 9C, source/drain (S/D) regions 146 are formed from the substrate portion 116. The S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

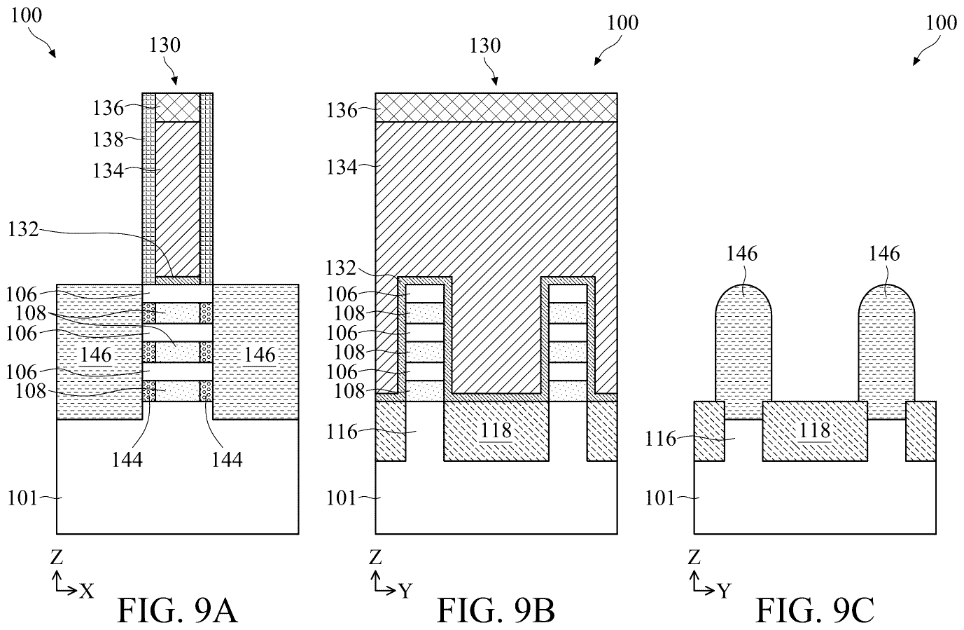

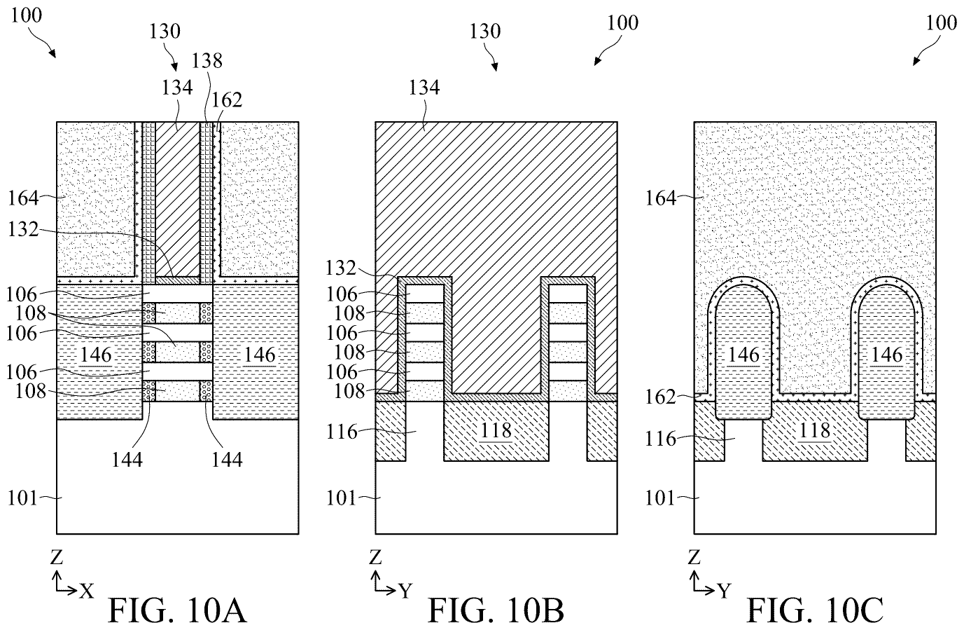

FIGS. 10A, 10B, and 10C are cross-sectional side views of one of various stages of manufacturing the semiconductor device structure 100 taken along line A-A, line B-B, and line C-C of FIG. 6, respectively, in accordance with some embodiments. In FIGS. 10A, 10B, and 10C, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. In some embodiments, the CESL 162 includes SiC, SiN, SiOCN, SiOC, SiCN, SiO, AlO, AlON, or AlN. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIGS. 10A and 10B.

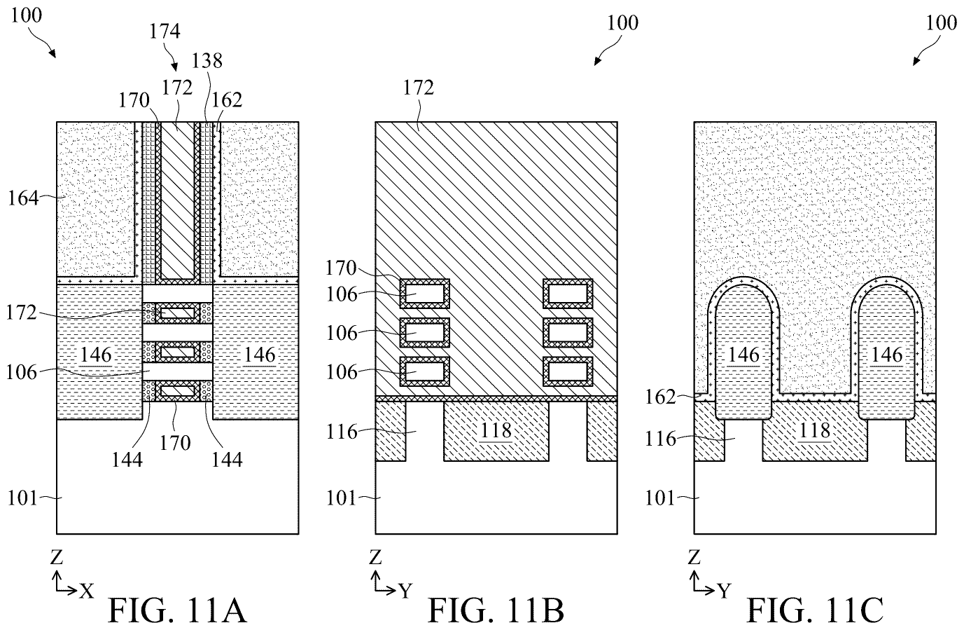

FIGS. 11A, 11B, and 11C are cross-sectional side views of one of various stages of manufacturing the semiconductor device structure 100 taken along line A-A, line B-B, and line C-C of FIG. 6, respectively, in accordance with some embodiments. As shown in FIGS. 11A and 11B, the sacrificial gate structure 130 and the second semiconductor layers 108 are removed. The removal of the sacrificial gate structure 130 and the semiconductor layers 108 forms an opening between gate spacers 138 and between first semiconductor layers 106. The ILD layer 164 protects the S/D regions 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the gate spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

After the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

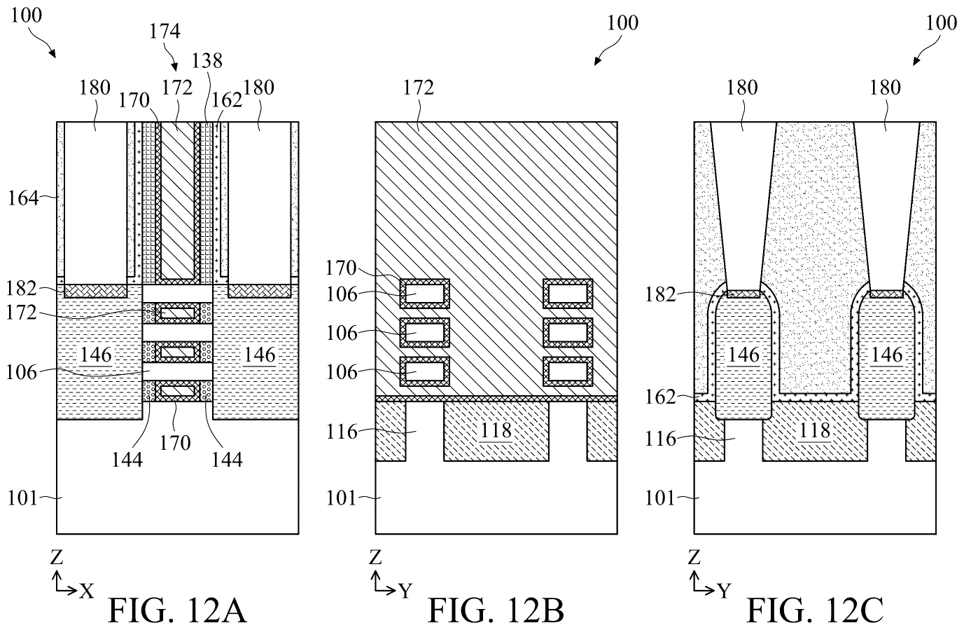

FIGS. 12A, 12B, and 12C are cross-sectional side views of one of various stages of manufacturing the semiconductor device structure 100 taken along line A-A, line B-B, and line C-C of FIG. 6, respectively, in accordance with some embodiments. As shown in FIGS. 12B and 12C, conductive contacts 180 are formed in the ILD layer 164 and the CESL 162. The conductive contacts 180 are electrically connected to the corresponding S/D regions 146 via silicide layers 182. The conductive contact 180 may be electrically conductive and may include a material having one or more of Ru, Mo, Co, Ir, W, Ti, Ta, Cu, TiN or TaN. The conductive contacts 180 may be formed by any suitable method, such as electro-chemical plating (ECP) or PVD. The silicide layers 182 may be formed by any suitable process. In some embodiments, a metal layer (not shown) is first formed on the semiconductor device structure 100. The metal layer may include Ti, Ni, Ru, Co, W, or other suitable metal. The metal layer may be deposited by any suitable process, such as ALD, CVD, or PVD. After the metal layer deposition, an annealing process is performed to react the S/D regions 146 with the metal layer, thereby forming the silicide layers 182. The silicide layer 192 may include any suitable material, such as NiSi, TiSi, CoSi, RuSi, or wSi. A planarization process, such as a CMP process, may be performed so the top surfaces of the gate electrode layers 172 and the top surfaces of the conductive contacts 180 are substantially co-planar, as shown in FIG. 12A. In some embodiments, the conductive contact 180 has a critical dimension ranging from about 5 nm to about 50 nm.

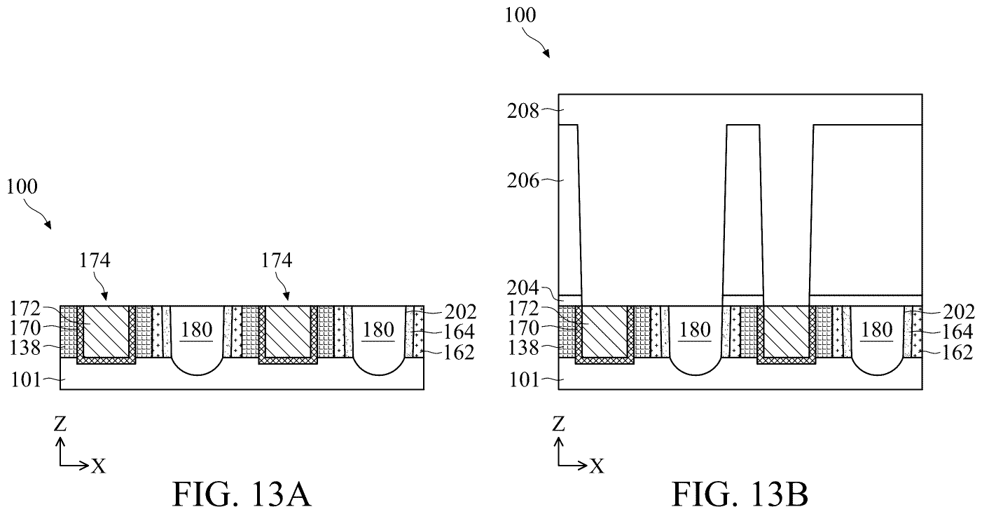

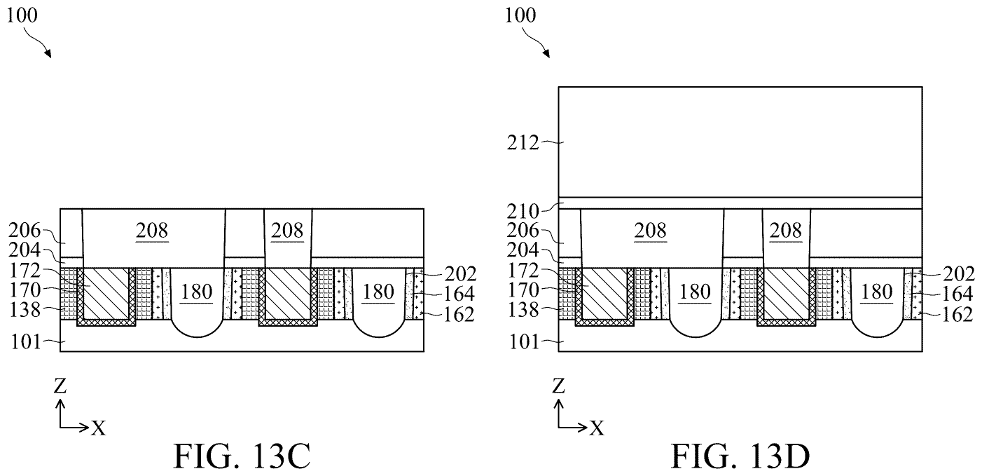

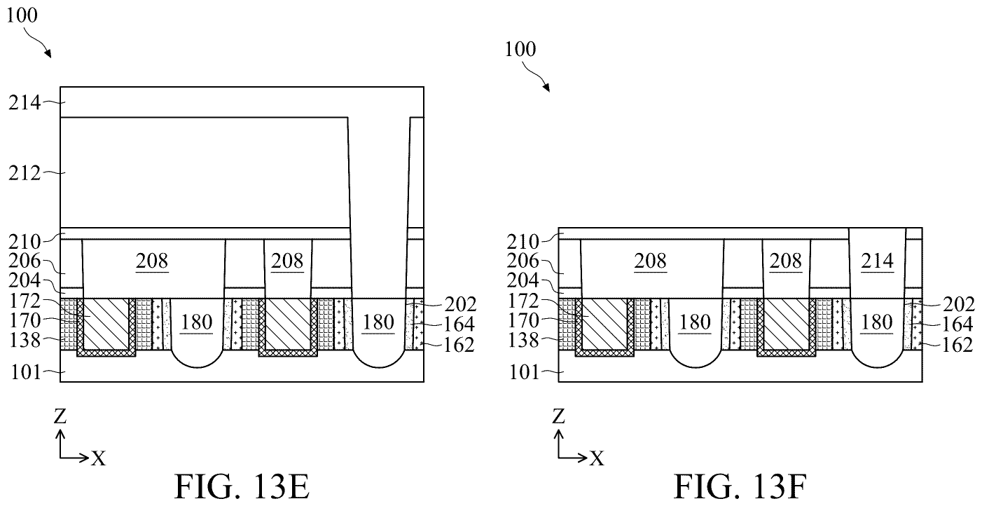

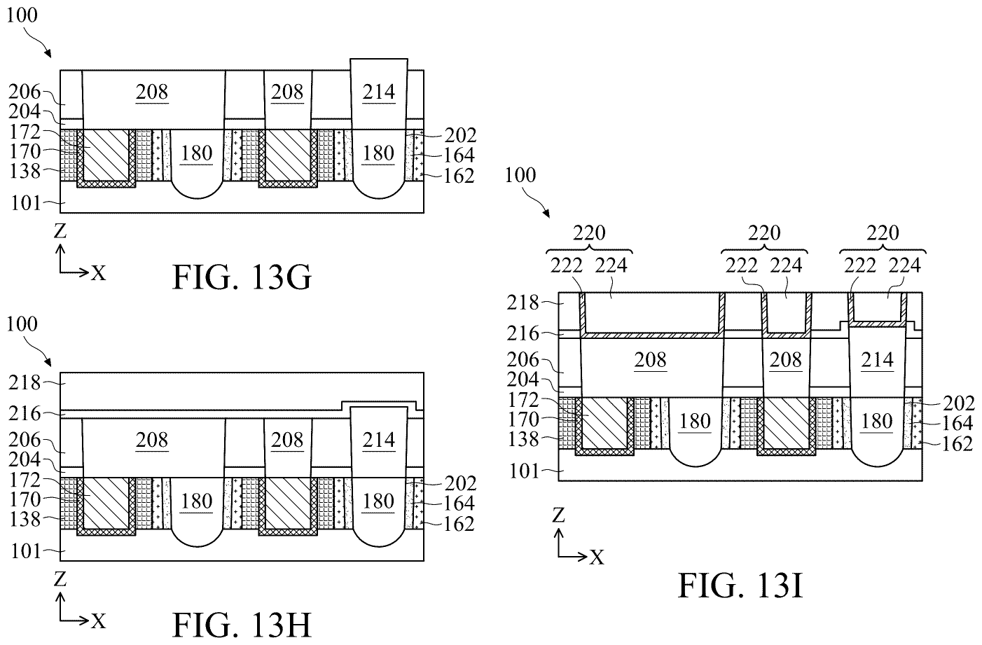

FIGS. 13A-13H are cross-sectional side views of various stages of manufacturing the semiconductor device structure 100 taken along line A-A of FIG. 6, in accordance with some embodiments. Various components on the substrate 101 are omitted in FIGS. 13A-13H for clarity. As shown in FIG. 13A, in some embodiments, the conductive contact 180 is formed between a liner 202. The liner may include any suitable dielectric material, such as SiN. In some embodiments, the liner 202 includes Co, W, Ru, Al, Mo, Ti, TiN, Cu, TaN, or other suitable material. In some embodiments, the liner 202 is not present, and the conductive contact 180 is in contact with the ILD layer 164. Next, as shown in FIG. 13B, an etch stop layer 204 and another ILD layer 206 are formed on the ILD layer 164, the gate structures 174, and the conductive contacts 180. The etch stop layer 204 may include the same material as the CESL 162, and the ILD layer 206 may include the same material as the ILD layer 164. A conductive feature 208 is formed in the ILD layer 206 and the etch stop layer 204. The conductive feature 208 may include an electrically conductive material, such as Ru, Mo, Co, Ir, W, Ti, Ta, Cu, TIN, TaN or combinations thereof, or other suitable material. The conductive feature 208 may be formed by any suitable process, such as PVD or ECP. In some embodiments, the conductive feature 208 is electrically connected to the gate electrode layers 172. In some embodiments, the conductive feature 208 is electrically connected to the gate electrode layers 172 and the conductive contact 180 located adjacent one or more gate electrode layers 172, as shown in FIG. 13B. In some embodiments, the conductive feature 208 is in direct contact with the gate electrode layer 172.

As shown in FIG. 13C, a planarization process, such as a CMP process, is performed, and the top surfaces of the conductive features 208 and the top surface of the ILD layer 206 are substantially co-planar. The conductive features 208 are electrically connected to the gate electrode layers 172 (and an adjacent conductive contact 180 in some embodiments). The conductive feature 208 electrically connecting to both the gate electrode layer 172 and the conductive contact 180 may be referred to as a butted contact. In some embodiments, the conductive feature 208 has a critical dimension ranging from about 5 nm to about 50 nm. Next, as shown in FIG. 13D, a CMP stop layer 210 and another ILD layer 212 are formed over the ILD layer 206 and the conductive features 208. The CMP stop layer 210 may include any suitable material, such as SiC, SiN, SiOCN, SiOC, SiCN, SiO, AlO, AlON, or AlN. The CMP stop layer 210 may be formed by any suitable process, such as ALD, CVD, or PVD. The ILD layer 212 may include the same material as the ILD layer 206 and may be deposited by the same process as the ILD layer 206. Next, as shown in FIG. 13E, conductive features 214 are formed in the ILD layer 212, the CMP stop layer 210, the ILD layer 206, and the etch stop layer 204. The conductive features 214 may include an electrically conductive material, such as Ru, Mo, Co, Ir, W, Ti, Ta, Cu, TIN, TaN or combinations thereof, or other suitable material. In some embodiments, the conductive feature 214 includes a material different from the conductive feature 208. For example, in some embodiments, the conductive features 208 are for providing signal or power to the gate electrode layers 172, and the conductive feature 208 includes Ti or W, which can lead to higher yield. The conductive features 214 are for providing signal or power to the S/D regions 146, and the conductive feature 214 includes Ru, Mo, or Ir, which can lead to reduced resistance. The conductive feature 214 may be formed by any suitable process, such as PVD or ECP. In some embodiments, the conductive feature 214 is in direct contact with a conductive contact 180, which is electrically connected to a S/D region 146 via a silicide layer 182 (FIGS. 12A, 12C)

As shown in FIG. 13F, a CMP process is performed to remove portions of the conductive feature 214 and the ILD layer 212. The CMP process is stopped when the CMP stop layer 210 is exposed. As described above, in some embodiments, the conductive features 208 and the conductive features 214 are made of different materials, such as different metals. Thus, both the conductive features 208 and the conductive features 214 are exposed to the slurry of the CMP process, which may lead to galvanic corrosion. Galvanic corrosion refers to corrosion damage induced when two dissimilar materials (i.e., the conductive features 208, 214) are coupled in a corrosive electrolyte (i.e., slurry of the CMP process). In order to prevent galvanic corrosion, the CMP stop layer 210 is used to cover the conductive features 208 while the conductive features 214 are exposed during the CMP process. In some embodiments, the CMP stop layer 210 has a thickness ranging from about 1 nm to about 10 nm. As shown in FIG. 13F, the thickness of the CMP stop layer 210 defines the additional height of the conductive features 214 along the Z direction compared to the height of the conductive features 208. If the thickness of the CMP stop layer 210 is less than about 1 nm, the CMP stop layer 210 may not sufficiently cover the conductive features 208 during the CMP process. On the other hand, if the thickness of the CMP stop layer 210 is greater than about 10 nm, the conductive features 214 may be too close to the conductive features located in the level above an adjacent conductive feature. As a result, parasitic capacitance may be increased. As shown in FIG. 13F, after the CMP process, the top surface of the CMP stop layer 210 and the top surfaces of the conductive features 214 are substantially co-planar. In some embodiments, the conductive feature 214 has a critical dimension ranging from about 5 nm to about 50 nm.

In some embodiments, the CMP stop layer 210 is removed after the CMP process, as shown in FIG. 13G. The CMP stop layer 210 may be removed by any suitable process, such as an etch process. The etch process may be a selective etch process that does not substantially affect the conductive features 214. After the removal of the CMP stop layer 210, the conductive features 214 extend to a level above the top surfaces of the conductive features 208 and the ILD layer 206. A portion of the side surface of each conductive feature 214 is exposed, as shown in FIG. 13G. In some embodiments, the bottom surfaces of the conductive features 208 and the bottom surfaces of the conductive features 214 are substantially co-planar, and the top surfaces of the conductive features 214 extend above the level of the top surfaces of the conductive features 208, as shown in FIG. 13G.

Next, as shown in FIG. 13H, another etch stop layer 216 is deposited on the top surfaces of the conductive features 208, the ILD layer 206, and the conductive features 214, and the etch stop layer 216 is also deposited on the exposed portion of the side surface of each conductive feature 214. An intermetal dielectric (IMD) layer 218 is deposited on the etch stop layer 216. The etch stop layer 216 may include the same material as the etch stop layer 204 and may be formed by the same process as the etch stop layer 204. The IMD layer 218 is made from a dielectric material, such as SiOₓ, SiOₓC_{y}H_{z}, or SiOₓC_{y}, where x, y and z are integers or non-integers. In some embodiments, the IMD layer 218 includes a dielectric material having a k value ranging from about 1 to about 5. As shown in FIG. 13I, conductive features 220 are formed in the IMD layer 218 and the etch stop layer 216. In some embodiments, each conductive feature 220 includes a barrier layer 222 and a conductive material 224. The barrier layer 222 may include Co, W, Ru, Al, Mo, Ti, TIN, Cu, TaN, or other suitable material, and the conductive material 224 may include Co, W, Ru, Al, Mo, Ti, TIN, Cu, TaN, or other suitable material. In some embodiments, the conductive material 224 includes a metal that is susceptible to diffusion, such as Cu, and the barrier layer 222 may include Ti, TiN, or TaN that may prevent the metal diffusion from the conductive material 224 to the IMD layer 218. In some embodiments, the conductive material 224 is not susceptible to diffusion, and the barrier layer 222 is not present. In some embodiments, the thickness of the barrier layer 222 may range from about 0.5 nm to about 10 nm. In some embodiments, a planarization process, such as a CMP process, is performed, so the top surfaces of the conductive features 220 and the IMD layer 218 are substantially co-planar. In some embodiments, as shown in FIG. 13I, the etch stop layer 216 is in contact with a portion of a side surface of each conductive feature 220 and a portion of a side surface of each conductive feature 214.

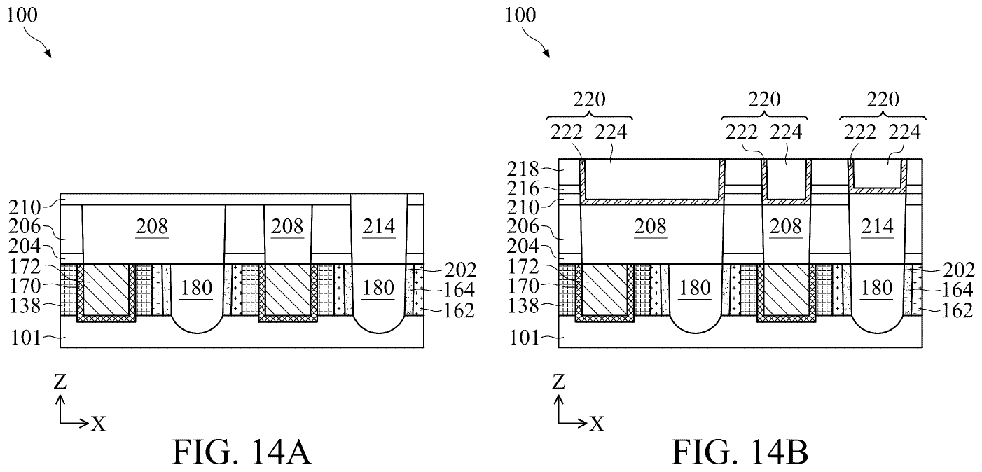

FIGS. 14A-14B are cross-sectional side views of various stages of manufacturing the semiconductor device structure 100 taken along line A-A of FIG. 6, in accordance with alternative embodiments. As shown in FIG. 14A, the CMP process is performed to expose the CMP stop layer 210 and the conductive features 214, which is at the same manufacturing stage shown in FIG. 13F. Next, instead of removing the CMP stop layer 210, the etch stop layer 216 is deposited on the CMP stop layer 210 and the conductive features 214, as shown in FIG. 14B. The ILD layer 218 is deposited on the etch stop layer 216, and the conductive features 220 are formed in the ILD layer 218 and the etch stop layer 216. The conductive features 220 disposed over the conductive features 208 are also formed in the CMP stop layer 210, as shown in FIG. 14B. In some embodiments, as shown in FIG. 14B, the CMP stop layer 210 is in contact with a portion of a side surface of each conductive feature 220 disposed over a gate electrode layer 172 and a portion of a side surface of each conductive feature 214. The etch stop layer 216 is in contact with a portion of a side surface of each conductive feature 220, as shown in FIG. 14B.

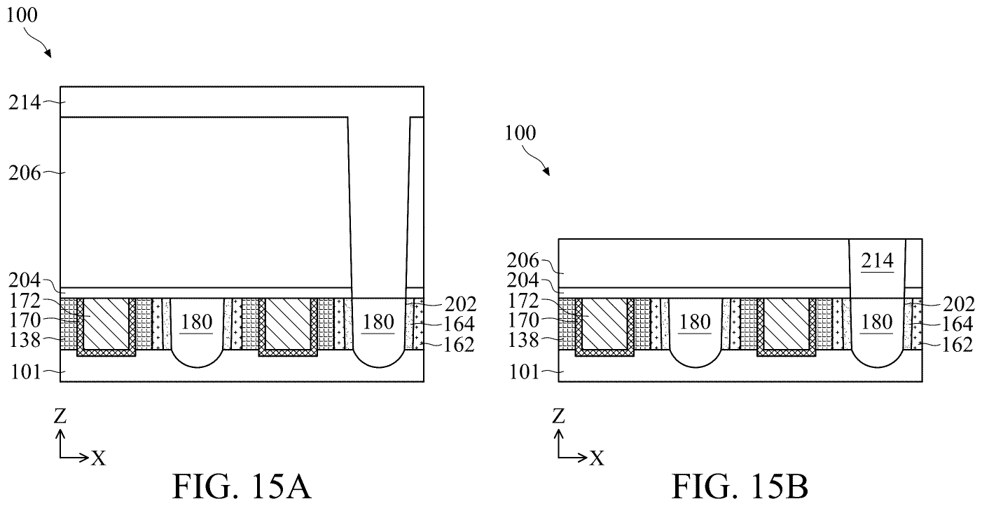

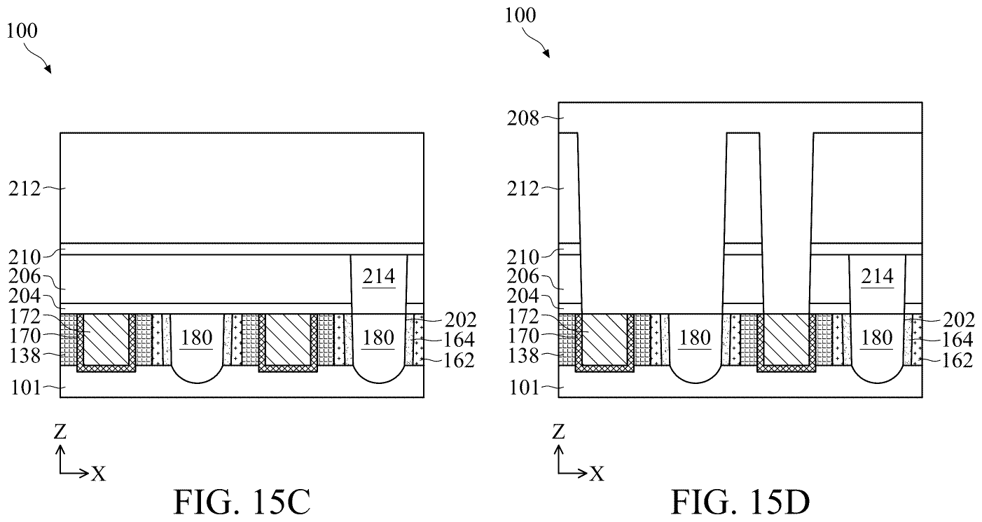

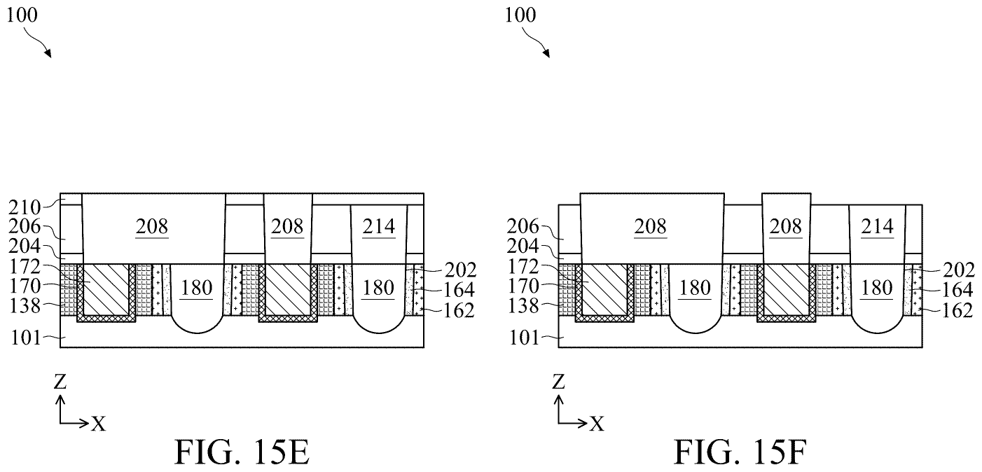

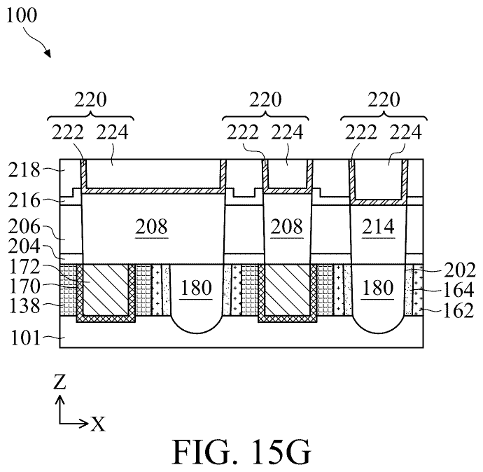

FIGS. 15A-15G are cross-sectional side views of various stages of manufacturing the semiconductor device structure 100 taken along line A-A of FIG. 6, in accordance with alternative embodiments. In some embodiments, as shown in FIGS. 13A-13H and 14A-14B, the conductive features 208 are formed prior to the formation of the conductive features 214. In some embodiments, the conductive features 214 are formed prior to the formation of the conductive features 208. As shown in FIG. 15A, after the formation of the conductive contacts 180, the etch stop layer 204 and the ILD layer 206 are deposited on the semiconductor device structure 100. Next, the conductive features 214 are formed in the ILD layer 206 and the etch stop layer 204. A planarization process, such as a CMP process, is performed on the semiconductor device structure 100, as shown in FIG. 15B.

As shown in FIG. 15C, the CMP stop layer 210 is deposited on the ILD layer 206 and the conductive features 214, and the ILD layer 212 is deposited on the CMP stop layer 210. Next, the conductive features 208 are formed in the ILD layer 212, the CMP stop layer 210, the ILD layer 206, and the etch stop layer 204, as shown in FIG. 15D. A CMP process is performed to expose the CMP stop layer 210, as shown in FIG. 15E. The CMP stop layer 210 covers the conductive features 214 during the CMP process. Thus, the conductive features 208 are exposed to the slurry of the CMP process, while the conductive features 214 are protected by the CMP stop layer 210. As a result, galvanic corrosion is prevented. In some embodiments, the CMP stop layer 210 is removed, as shown in FIG. 15F. After the removal of the CMP stop layer 210, the top surfaces of the conductive features 214 and the top surface of the ILD layer 206 are substantially co-planar, and the top surfaces of the conductive features 208 extend to a level above the top surfaces of the conductive features 214 and the ILD layer 206. A portion of the side surface of each conductive feature 208 is exposed, as shown in FIG. 15F. In some embodiments, the bottom surfaces of the conductive features 208 and the bottom surfaces of the conductive features 214 are substantially co-planar, and the top surfaces of the conductive features 208 extend above the level of the top surfaces of the conductive features 214, as shown in FIG. 15F.

Next, as shown in FIG. 15G, the etch stop layer 216 is deposited on the top surfaces of the conductive features 208, the ILD layer 206, and the conductive features 214, and the etch stop layer 216 is also deposited on the exposed portion of the side surface of each conductive feature 208. The IMD layer 218 is deposited on the etch stop layer 216, and the conductive features 220 are formed in the IMD layer 218 and the etch stop layer 216. In some embodiments, a planarization process, such as a CMP process, is performed, so the top surfaces of the conductive features 220 and the IMD layer 218 are substantially co-planar. In some embodiments, the etch stop layer 216 is in contact with a portion of a side surface of each conductive feature 208 and a portion of a side surface of each conductive feature 220 disposed over a conductive feature 214.

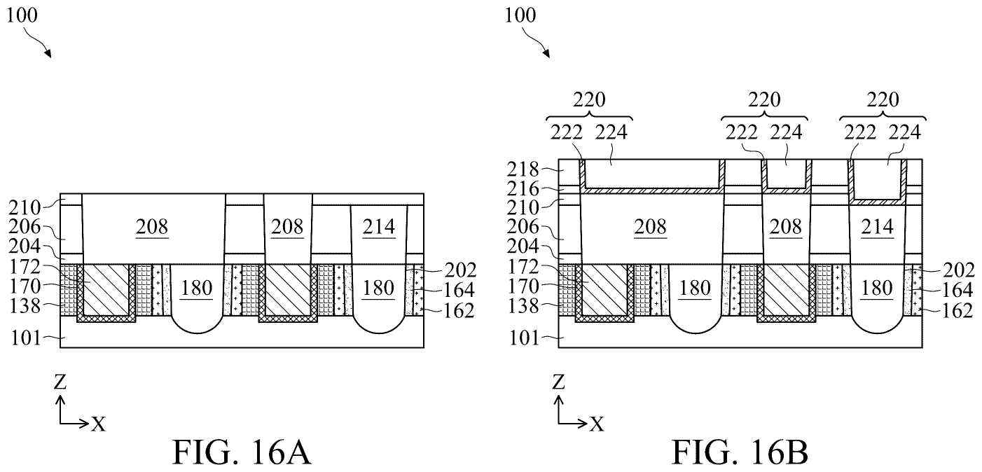

FIGS. 16A-16B are cross-sectional side views of various stages of manufacturing the semiconductor device structure 100 taken along line A-A of FIG. 6, in accordance with alternative embodiments. As shown in FIG. 16A, the CMP process is performed to expose the CMP stop layer 210 and the conductive features 208, which is at the same manufacturing stage shown in FIG. 15E. Next, instead of removing the CMP stop layer 210, the etch stop layer 216 is deposited on the CMP stop layer 210 and the conductive features 208, as shown in FIG. 16B. The ILD layer 218 is deposited on the etch stop layer 216, and the conductive features 220 are formed in the ILD layer 218 and the etch stop layer 216. The conductive features 220 disposed over the conductive features 214 are also formed in the CMP stop layer 210, as shown in FIG. 16B. In some embodiments, as shown in FIG. 16B, the CMP stop layer 210 is in contact with a portion of a side surface of each conductive feature 208 and a portion of a side surface of each conductive feature 220 disposed over a conductive feature 214. The etch stop layer 216 is in contact with a portion of a side surface of each conductive feature 220, as shown in FIG. 16B.

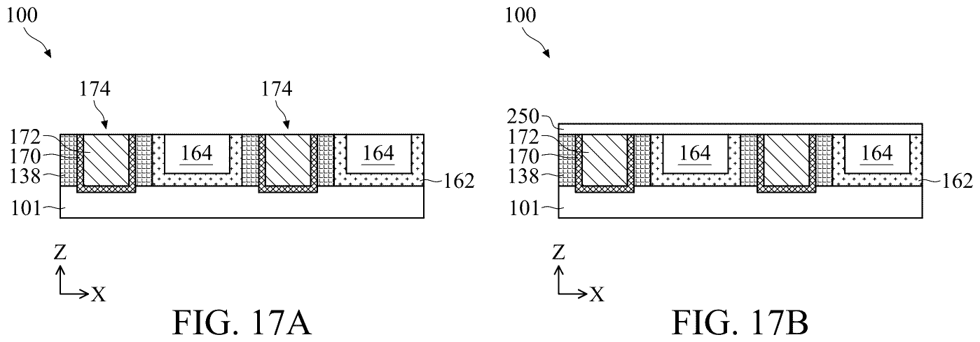

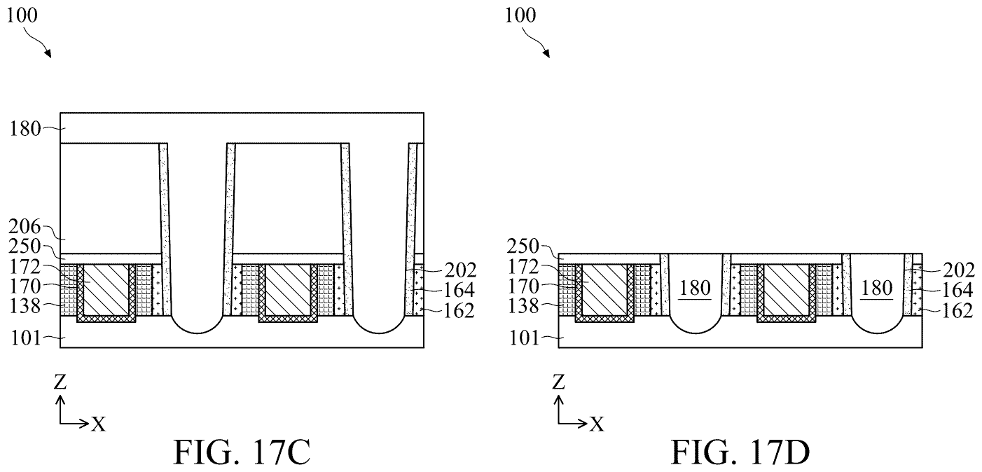

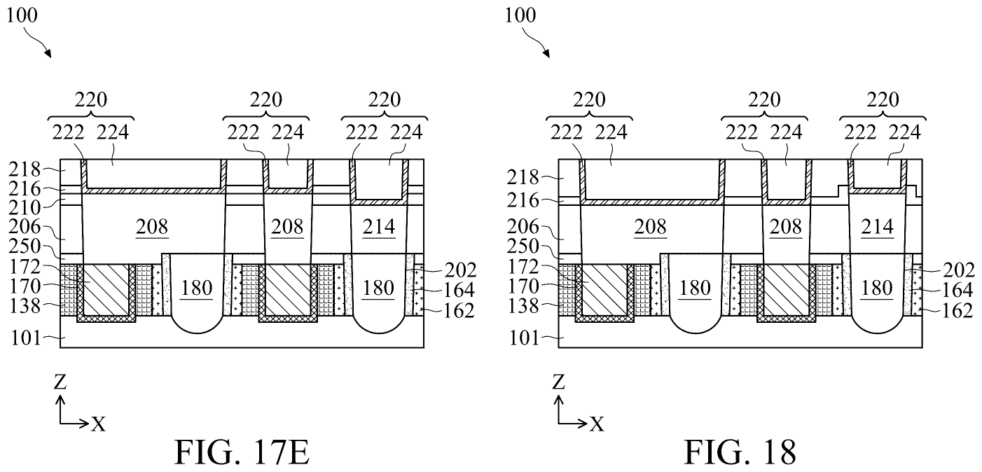

FIGS. 17A-17E are cross-sectional side views of various stages of manufacturing the semiconductor device structure 100 taken along line A-A of FIG. 6, in accordance with alternative embodiments. In some embodiments, the gate electrode layer 172 and the conductive contact 180 (FIG. 12A) include different materials. Thus, in some embodiments, the CMP process performed after the formation of the conductive contacts 180 may lead to galvanic corrosion. A CMP stop layer may be utilized to cover the gate electrode layers 172 during the CMP process. As shown in FIG. 17A, the gate electrode layers 172 are formed, which is at the same manufacturing stage shown in FIGS. 11A, 11B, 11C. Next, as shown in FIG. 17B, a CMP stop layer 250 is deposited on the gate electrode layers 172 and the ILD layer 164. The CMP stop layer 250 is also deposited on the spacers 138, the gate dielectric layers 170, and the CESL 162. The CMP stop layer 250 may include the same material as the CMP stop layer 210 and may be formed by the same process as the CMP stop layer 210. The CMP stop layer 250 may have the same thickness as the CMP stop layer 210.

As shown in FIG. 17C, the ILD layer 206 is deposited on the CMP stop layer 250, and the liner 202 and the conductive contacts 180 are formed in the ILD layer 206. The liner 202 and the conductive contacts 180 are formed through the ILD layer 206, the CMP stop layer 250, the ILD layer 164, and the CESL 162. Next, a CMP process is performed to remove portions of the conductive contacts 180, the ILD layer 206, and the liner 202 until the CMP stop layer 250 is exposed. During the CMP process, the gate electrode layers 172, which may be made of a metal different from the metal of the conductive contacts 180, are covered by the CMP stop layer 250. As a result, galvanic corrosion is prevented. As shown in FIG. 17D, the top surface of the CMP stop layer 250 and the top surfaces of the conductive contacts 180 may be substantially co-planar.

Next, the ILD layer 206 is deposited on the CMP stop layer 250, as shown in FIG. 17E. Processes described in FIGS. 13B-13H or in FIGS. 13B-13F and 14B may be performed to form the conductive features 208, 214, the CMP stop layer 210, the etch stop layer 216, the IMD layer 218, and the conductive features 220, as shown in FIG. 17E. In some embodiments, the CMP stop layer 210 remains in the semiconductor device structure 100. In some embodiments, the CMP stop layer 210 is removed. In some embodiments, the conductive features 214 are formed prior to the formation of the conductive features 208. As a result, the height of the conductive features 208 is substantially greater than the height of the conductive features 214, as shown in FIG. 17E.

FIG. 18 is a cross-sectional side view of one of various stages of manufacturing the semiconductor device structure 100 taken along line A-A of FIG. 6, in accordance with alternative embodiments. In some embodiments, the CMP stop layer 210 is removed, and the conductive features 208 are formed prior to the formation of the conductive features 214.

Embodiments of the present disclosure provide a semiconductor device structure 100 including first conductive feature 208 disposed on and in contact with a gate electrode layer 172 and a second conductive feature 214 disposed on and in contact with a conductive contact 180. The height of the first conductive feature 208 is different from the height of the second conductive feature 208 as a result of a CMP stop layer 210 formed on either the first conductive feature 208 or the second conductive feature 214. Some embodiments may achieve advantages. For example, with the CMP stop layer 210 formed on either the first conductive feature 208 or the second conductive feature 214 during a CMP process, one of the first and second conductive features 208, 214 is exposed during the CMP process, which can prevent galvanic corrosion.

An embodiment is a semiconductor device structure. The structure includes a gate electrode layer disposed over a substrate, a first source/drain region disposed over the substrate, a conductive contact disposed over the first source/drain region, a first dielectric layer disposed over the gate electrode layer and the conductive contact, a first conductive feature disposed in the first dielectric layer, a second conductive feature disposed in the first dielectric layer, and a second dielectric layer disposed on the first dielectric layer. The second dielectric layer is in contact with a portion of a side surface of the second conductive feature.

Another embodiment is a semiconductor device structure. The structure includes a gate electrode layer disposed over a substrate, a source/drain region disposed over the substrate, a conductive contact disposed over the source/drain region, a first dielectric layer disposed over the gate electrode layer and the conductive contact, a first conductive feature disposed in the first dielectric layer, a second conductive feature disposed in the first dielectric layer, a third conductive feature disposed on and in contact with the first conductive feature, a fourth conductive feature disposed on and in contact with the second conductive feature, and a second dielectric layer disposed on the first dielectric layer. The second dielectric layer is in contact with a portion of a side surface of the second conductive feature and a first portion of a side surface of the third conductive feature. The structure further includes a third dielectric layer disposed on the second dielectric layer, and the third dielectric layer is in contact with a portion of a side surface of the fourth conductive feature and a second portion of the side surface of the third conductive feature.

A further embodiment is a method. The method includes forming a first dielectric layer over a substrate, and the substrate includes a gate electrode layer, a source/drain region, and a conductive contact disposed over the source/drain region. The method further includes forming a first conductive feature in the first dielectric layer, depositing a second dielectric layer on the first conductive feature and the first dielectric layer, depositing a third dielectric layer on the second dielectric layer, forming a second conductive feature in the first, second, and third dielectric layers, and performing a chemical mechanical polishing process to expose the second dielectric layer and the second conductive feature. The first conductive feature is covered by the second dielectric layer during the chemical mechanical polishing process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a gate electrode layer disposed over a substrate;
a first source/drain region disposed over the substrate;
a conductive contact disposed over the first source/drain region;
a first dielectric layer disposed over the gate electrode layer and the conductive contact;
a first conductive feature disposed in the first dielectric layer;
a second conductive feature disposed in the first dielectric layer; and
a second dielectric layer disposed on the first dielectric layer, wherein the second dielectric layer is in contact with a portion of a side surface of the second conductive feature.

2. The semiconductor device structure of claim 1, further comprising spacers disposed on opposite sides of the gate electrode layer and a third dielectric layer disposed on the spacers, wherein the first dielectric layer is disposed on the third dielectric layer.

3. The semiconductor device structure of claim 2, wherein the first and second conductive features are disposed in the third dielectric layer.

4. The semiconductor device structure of claim 2, wherein a top surface of the third dielectric layer and a top surface of the conductive contact are substantially co-planar.

5. The semiconductor device structure of claim 1, further comprising a fourth dielectric layer disposed on the second dielectric layer.

6. The semiconductor device structure of claim 5, further comprising a third conductive feature disposed in the fourth dielectric layer and the second dielectric layer, wherein the third conductive feature is disposed on and in contact with the first conductive feature.

7. The semiconductor device structure of claim 6, further comprising a fourth conductive feature disposed in the fourth dielectric layer and the second dielectric layer, wherein the fourth conductive feature is disposed on and in contact with the second conductive feature, and a top surface of the third conductive feature and a top surface of the fourth conductive feature are substantially co-planar.

8. The semiconductor device structure of claim 1, wherein the first conductive feature is disposed on and in contact with the gate electrode layer, and the second conductive feature is disposed on and in contact with the conductive contact.

9. The semiconductor device structure of claim 1, wherein the first conductive feature is disposed on and in contact with the conductive contact, and the second conductive feature is disposed on and in contact with the gate electrode layer.

10. A semiconductor device structure, comprising:
a gate electrode layer disposed over a substrate;
a source/drain region disposed over the substrate;
a conductive contact disposed over the source/drain region;
a first dielectric layer disposed over the gate electrode layer and the conductive contact;
a first conductive feature disposed in the first dielectric layer;
a second conductive feature disposed in the first dielectric layer;
a third conductive feature disposed on and in contact with the first conductive feature;
a fourth conductive feature disposed on and in contact with the second conductive feature;
a second dielectric layer disposed on the first dielectric layer, wherein the second dielectric layer is in contact with a portion of a side surface of the second conductive feature and a first portion of a side surface of the third conductive feature; and
a third dielectric layer disposed on the second dielectric layer, wherein the third dielectric layer is in contact with a portion of a side surface of the fourth conductive feature and a second portion of the side surface of the third conductive feature.

11. The semiconductor device structure of claim 10, further comprising a fourth dielectric layer disposed on the third dielectric layer, wherein the third and fourth conductive features are disposed in the third and fourth dielectric layers.

12. The semiconductor device structure of claim 11, wherein a top surface of the third conductive feature and a top surface of the fourth conductive feature are substantially co-planar.

13. The semiconductor device structure of claim 10, further comprising spacers disposed on opposite sides of the gate electrode layer and a fifth dielectric layer disposed on the spacers, wherein the first dielectric layer is disposed on the fifth dielectric layer.

14. The semiconductor device structure of claim 13, wherein the first and second conductive features are disposed in the fifth dielectric layer.

15. The semiconductor device structure of claim 13, wherein a top surface of the fifth dielectric layer and a top surface of the conductive contact are substantially co-planar.

16. A method, comprising:
forming a first dielectric layer over a substrate, wherein the substrate comprises a gate electrode layer, a source/drain region, and a conductive contact disposed over the source/drain region;
forming a first conductive feature in the first dielectric layer;
depositing a second dielectric layer on the first conductive feature and the first dielectric layer;
depositing a third dielectric layer on the second dielectric layer;
forming a second conductive feature in the first, second, and third dielectric layers; and
performing a chemical mechanical polishing process to expose the second dielectric layer and the second conductive feature, wherein the first conductive feature is covered by the second dielectric layer during the chemical mechanical polishing process.

17. The method of claim 16, further comprising:
removing the second dielectric layer to expose top surfaces of the first and second conductive features and a portion of a side surface of the second conductive feature; and
depositing a fourth dielectric layer on the first dielectric layer and the first and second conductive features, wherein the fourth dielectric layer is deposited on the exposed portion of the side surface of the second conductive feature.

18. The method of claim 16, further comprising depositing a fourth dielectric layer on the second dielectric layer and the second conductive feature.

19. The method of claim 16, wherein the first conductive feature is formed on the gate electrode layer, and the second conductive feature is formed on the conductive contact.

20. The method of claim 16, wherein the first conductive feature is formed on the conductive contact, and the second conductive feature is formed on the gate electrode layer.
